(19) United States
(12) Patent Application Publication
(10) Pub. No.: US 2024/0036561 A1
(43) Pub. Date: Feb. 1, 2024

(54) Production Line Design Device, Production Line Design System, and Production Line Design Method

(71) Applicant: Hitachi, Ltd., Chiyoda-ku, Tokyo (JP)

(72) Inventors: Takahiro NAKANO, Tokyo (JP); Daiki KAJITA, Tokyo (JP); Daisuke TSUTSUMI, Tokyo (JP)

(21) Appl. No.: 18/267,544

(22) PCT Filed: Sep. 29, 2021
(86) PCT No.: PCT/JP2021/035913

§ 371 Date: Jun. 15, 2023

(30) Foreign Application Priority Data
Feb. 26, 2021 (JP) 2021-030479

(51) Int. Cl. G05B 19/418

(52) U.S. Cl. CPC G05B 19/41885

(57) ABSTRACT

Provided is a quasi-optimal solution for a production line such that a KPI is further improved without deteriorating production throughput after the production line is designed. The invention includes: a storage unit configured to store product CAD information pertaining to a shape of a product, component attribute information pertaining to an attribute of a component, module group specification information pertaining to a specification of a module group implemented by combining attributes of modules as a production resource of the product for respective work processes of the component, and module specification information pertaining to a specification of the module; and a computation unit configured to design a production line by executing an equipment design, a control design, a process design, and an arrangement design in this order. The computation unit includes a candidate module group extraction unit that is a functional unit configured to use the information stored in the storage unit to perform the equipment design, and that is configured to extract a configuration pattern of a candidate module group obtained by combining a candidate of the module group that is work-compatible for each component of the product and the module that is handled in the candidate of the module group.

### TECHNICAL FIELD

The invention relates to a production line design device, a production line design system, and a production line design method. The invention claims priority of Japanese Patent Application number 2021-030479, filed on Feb. 26, 2021, and regarding the designated countries that are permitted to be incorporated by reference in the literature, the content of that application is incorporated into the present application by reference.

### BACKGROUND ART

PTL 1 relates to a method for designing a manufacturing line, and discloses that “the information is exchanged among the process design, the layout design, and the production capacity design via the product and manufacturing database, and the process flow is created based on the shape of the product and the component configuration information of the product at least, the manufacturing resource is laid out and arranged based on the process flow, the manufacturing resource information including at least the facility and worker for manufacturing the product, and the constraint condition of the place in which the product is manufactured, the manufacturing line virtual model is generated based on the layout design result and the production resource information, the motion of the manufacturing line is reproduced using the manufacturing line virtual model, and the production capacity of the manufacturing line is obtained.”

### CITATION LIST

### Patent Literature

PTL 1: JP2003-44115A

### SUMMARY OF INVENTION

### Technical Problem

In related art, when a production line of a factory is designed, an arrangement design, a control design, an equipment design, and the like are performed after a process design of a product is performed. However, since an operation of accessory equipment such as a conveyor, an automatic guided vehicle (AGV), a component supplying apparatus (supplier), and a place (table) is not taken into consideration during the process design, and when an operation design of the accessory equipment is performed after the process design, a problem may occur that tact balance is lost between respective devices and that production throughput is deteriorated.

PTL 1 discloses the method for designing a manufacturing line. However, in a technique of PTL 1, a control design and the like is performed after the process design, and a configuration of an equipment group including the accessory equipment is not considered. Therefore, a problem of the deterioration of the production throughput may occur.

The invention is made in view of the above problem, and an object thereof is to obtain a quasi-optimal solution for a production line such that a key performance indicator (KPI) is further improved without deteriorating a production throughput after a production line is designed.

### Solution to Problem

The present application includes a plurality of units that solves at least a part of the above problem. An example of the units is as follows. A production line design device according to an aspect of the invention for solving the above problem includes: a storage unit configured to store product CAD information pertaining to a shape of a product, component attribute information pertaining to an attribute of a component, module group specification information pertaining to a specification of a module group constituted by combining attributes of modules as a production resource of the product for respective work processes of the component, and module specification information pertaining to a specification of the module; and a computation unit configured to design a production line by executing an equipment design, a control design, a process design, and an arrangement design in this order. The computation unit includes a candidate module group extraction unit that is a functional unit configured to use the information stored in the storage unit to perform the equipment design, and that is configured to extract a configuration pattern of a candidate module group obtained by combining a candidate of the module group that is work-compatible for each component of the product and the module that is handled in the candidate of the module group.

### Advantageous Effects of Invention

According to the invention, the quasi-optimal solution for the production line can be obtained such that the KPI is further improved without deteriorating the production throughput after the production line is designed.

### BRIEF DESCRIPTION OF DRAWINGS

FIG. 1 is a diagram showing an example of a schematic configuration of a production line design system.

FIG. 2 is a diagram showing an example of component attribute information 122.

FIG. 3 is a diagram showing an example of module group specification information 124.

FIG. 4 is a diagram showing an example of module specification information 125.

FIG. 5 is a flowchart showing an example of production line design processing.

FIG. 6 is a diagram showing an example of a work partial order graph.

FIG. 7 is a flowchart showing an example of candidate module group extraction processing.

FIG. 8 is a flowchart showing an example of operation planning creating processing.

FIG. 9 is a diagram showing an example of an operation sequence between modules.

FIG. 10 is a flowchart showing an example of simultaneous optimization processing.

FIG. 11 is a diagram showing an example of optimization of a module configuration.

FIG. 12 is a screen example showing an example of production line display information.

FIG. 13 is a screen example showing an example of module group display information.

FIG. 14 is a screen example showing an example of edit screen information.

FIG. 15 is a diagram showing an example of a hardware configuration of a production line design device.

### DESCRIPTION OF EMBODIMENTS

Hereinafter, each embodiment of the invention will be described with reference to the drawings.

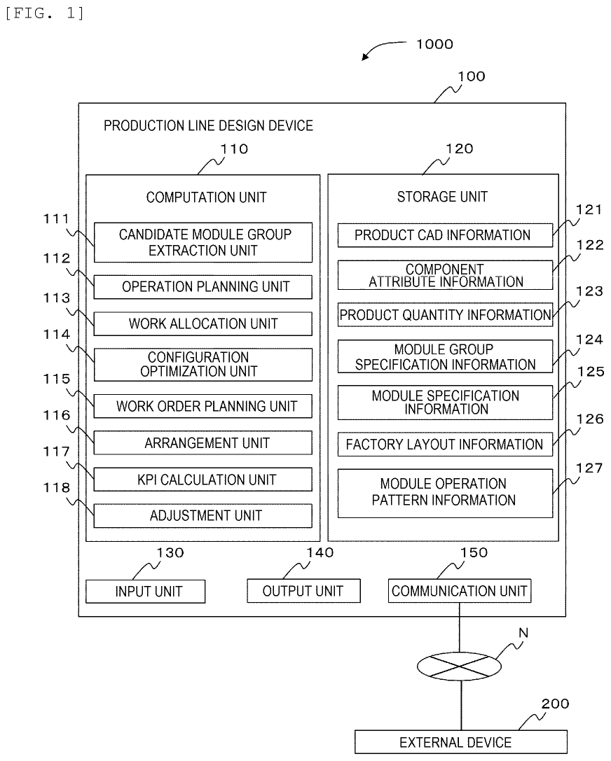

FIG. 1 is a diagram showing an example of a schematic configuration of a production line design system 1000 according to the present embodiment. As shown in the drawing, the production line design system 1000 includes a production line design device 100 and an external device 200. The production line design device 100 and the external device 200 are connected to be able to communicate with each other via a public network such as a communication cable or the Internet, and a network N such as a local area network (LAN) or a wide area network (WAN).

The external device 200 is, for example, a device used to display screen information generated by the production line design device 100 or to transmit an execution instruction of processing for the production line design device 100 or information used for the processing.

The production line design device 100 is a device for designing a production line. Specifically, the production line design device 100 relates to equipment for producing a product, and performs an equipment design, a control design, a process design, and an arrangement design. In order to perform such processing, the production line design device 100 includes a computation unit 110, a storage unit 120, an input unit 130, an output unit 140, and a communication unit 150.

The computation unit 110 is a functional unit that executes computation processing for performing various designs. Specifically, the computation unit 110 includes a candidate module group extraction unit 111, an operation planning unit 112, a work allocation unit 113, a configuration optimization unit 114, a work order planning unit 115, an arrangement unit 116, a KPI calculation unit 117, and an adjustment unit 118.

The candidate module group extraction unit 111 is a functional unit that performs processing pertaining to the equipment design, and extracts a candidate of a module group. Here, the module group is a group constituted by combining various modules as a production resource of the product. Specifically, the module group is implemented by combining various module attributes such as a work subject, work assistance, supply, and a place according to a work process.

The candidate module group extraction unit 111 extracts a candidate of the module group that performs a process associated with each component of the product. Specifically, the candidate module group extraction unit 111 generates a graph showing a partial order relation of the components using predetermined information (for example, component attribute information 122, module group specification information 124, and module specification information 125 to be described later), and extracts a candidate module group that performs a process associated with each component specified from the graph.

The candidate module group extraction unit 111 extracts a candidate of a module capable of handling each component for each module attribute of the extracted candidate module group.

The candidate module group extraction unit 111 generates a pattern of the candidate module group in which a candidate of the module group corresponding to a process attribute of the component is associated with a candidate of each module which corresponds to each module attribute provided in the candidate of the module group and can handle a target component.

The operation planning unit 112 is a functional unit that performs processing pertaining to the control design, and plans an operation of each candidate module group and an operation of each module. Specifically, the operation planning unit 112 performs generation of a combination pattern of modules provided in the candidate module group, creation of a work partial order plan for each module, calculation of a work time of each candidate module group and the candidate module, and the like.

The work allocation unit 113 is a functional unit that performs processing pertaining to a process plan, specifies a candidate module group that satisfies a restriction of a product quantity and has a low cost, based on the work time calculated for each candidate module group and an equipment cost, and allocates the work of each component to the candidate module group.

The configuration optimization unit 114 is a functional unit that performs processing pertaining to re-planning of the equipment due to optimization of the configuration, and performs reconfiguration of the equipment such as replacement of the modules or merging of the module groups.

The work order planning unit 115 is a functional unit that performs processing pertaining to the process plan, and plans a work order for the production line.

The arrangement unit 116 is a functional unit that performs processing pertaining to the arrangement design, and arranges the module groups in a factory layout. Specifically, the arrangement unit 116 generates an arrangement pattern of each module group in the factory layout as an arrangement plan.

The KPI calculation unit 117 is a functional unit that calculates a predetermined KPI value. Specifically, the KPI calculation unit 117 calculates the predetermined KPI value such as an operation rate, productivity, and the equipment cost in the production line or a unit of the module group.

The adjustment unit 118 is a functional unit that outputs an execution instruction of processing pertaining to adjustment to another functional unit. Specifically, when a module group configuration of the designed production line is changed, the execution instruction is output to another functional unit corresponding to the processing.

The storage unit 120 is a functional unit for storing various types of information. Specifically, the storage unit 120 includes product computer aided design (CAD) information 121, product quantity information 123, the module group specification information 124, the module specification information 125, factory layout information 126, and module operation pattern information 127.

The product CAD information 121 is information including a shape of the product, a work partial order relation of the components, and other attribute information. The work partial order relation of the components is indicated by nodes indicating the components and directed arcs indicating each assembly relation between the nodes. The product CAD information 121 includes the component attribute information 122 in which attribute information pertaining to the components of the product is registered.

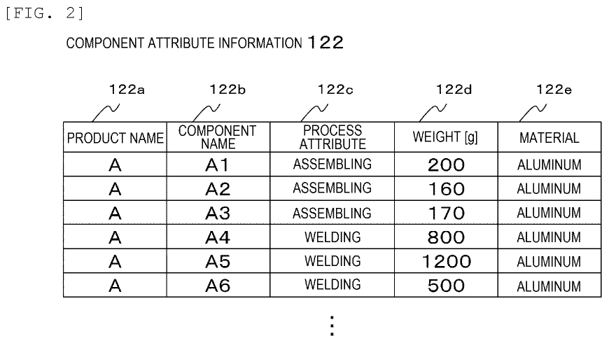

FIG. 2 is a diagram showing an example of the component attribute information 122. The component attribute information 122 is the attribute information of the components. Specifically, the component attribute information 122 has records associated with a product name 122a, a component name 122b, a process attribute 122c, a weight 122d, and a material 122e.

The product name 122a is information indicating a name of the product. The component name 122b is information indicating a name of each component. The process attribute 122c is information indicating the work process associated with the components. The process attribute 122c relates to various processes such as “assembling” and “welding”. The weight 122d is information indicating a weight of each component. The material 122e is information indicating a material of each component.

The product quantity information 123 is information pertaining to a quantity of a product to be produced or each component. Specifically, in the product quantity information 123, a production quantity of a target product or the component in a predetermined period is registered. For example, in the product quantity information 123, information such as the predetermined period “one month”, the target product “product X”, and the production amount “1000 units” is registered.

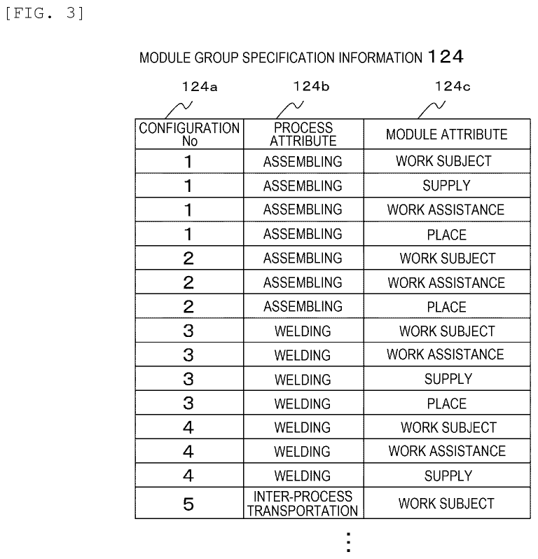

FIG. 3 is a diagram showing an example of the module group specification information 124. The module group specification information 124 is information pertaining to a specification of each module group. Specifically, in the module group specification information 124, attributes of various modules necessary for the work process handled by each module group are defined. More specifically, the module group specification information 124 has records associated with a configuration No 124a, a process attribute 124b, and a module attribute 124c.

The configuration No 124a is information for identifying the module group. The process attribute 124b is information indicating the work process corresponding to the module group, and is information common to the process attribute 122c of the component attribute information 122. The module attribute 124c is information indicating an attribute of each module, and has, for example, a “work subject”, “supply”, “work assistance”, and a “place”. For example, the module group associated with the configuration No 1 is a module group that performs the work process such as the “assembling” and indicates a module configuration such as the “work subject”, the “supply”, the “work assistance”, and the “place”. The module configuration has various combinations according to the configuration No 124a.

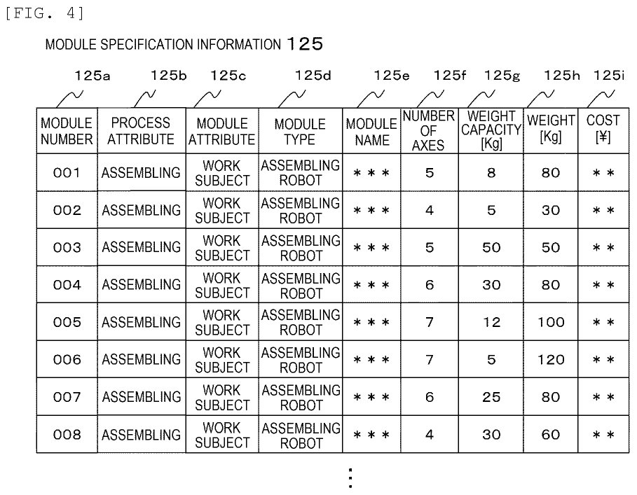

FIG. 4 is a diagram showing an example of the module specification information 125. The module specification information 125 is information indicating a specification of each module.

Specifically, the module specification information 125 has records associated with a module number 125a, a process attribute 125b, a module attribute 125c, a module type 125d, a module name 125e, the number of axes 125f, a weight capacity 125g, a weight 125h, and a cost 125i.

The module number 125a is information for identifying the module. The process attribute 125b is information indicating the work process in which a module is used, and is information common to the process attribute 124b of the module group specification information 124. The module attribute 125c is information indicating the attribute of the module, that is, the “work subject”, the “supply”, or the “work assistance”, and is information common to the module attribute 124c of the module group specification information 124.

The module type 125d is information indicating a type of each module. For example, the module type 125d in which the “assembling” and the “work subject” are respectively associated with the process attribute 125b and the module attribute 125c includes, for example, an “assembling robot”. The module type 125d in which the “welding” and the “work subject” are respectively associated with the process attribute 125b and the module attribute 125c includes, for example, a “welding robot”. The module type 125d in which “inter-process transportation” and the “work subject” are respectively associated with the process attribute 125b and the module attribute 125c, includes, for example, “AGV”. Other than the above, according to the combination of the process attribute 125b and the module attribute 125c, there are various work subjects such as a “person”, a “picking robot”, and a “processing machine”.

According to the combination of the process attribute 125b and the module attribute 125c, the work assistance includes various tools such as a “hand tool (of a robot)”. Examples of the supply include a “conveyor” and a “supplier (supply apparatus)”. Examples of the place include a “table” and a “storage (buffer)”.

The module name 125e is information indicating a name or a model number of the module. The number of axes 125f is information indicating the number of axes of the module, and is registered when the work subject is a device having an axis such as a robot. The weight capacity 125g is information indicating a weight that can be handled by the work subject. A weight target that can be handled by the work subject includes, for example, components, a product obtained by assembling the components, and a hand tool used by a robot. The weight 125h is information indicating a weight of the work subject. The cost 125i is information indicating a maintenance cost (expense) of the work subject.

The factory layout information 126 is information pertaining to a layout in a factory in which the production line is designed. Specifically, the factory layout information 126 includes a layout such as a placement available position of a module group constituting the production line.

The module operation pattern information 127 is information indicating an operation pattern of the module attribute. For example, when the module attribute is the work subject (for example, the assembling robot), operation patterns are registered such as “setting the work assistance (for example, a hand tool) in a work target”, “grasping a component from a supply place using the work assistance (hand tool)”, and “assembling the grasped component to another component”.

Returning to FIG. 1, description will be made. The input unit 130 is a functional unit that receives input of an instruction and information from a user. Specifically, the input unit 130 receives the input of the instruction and the information from the user via an input device provided in the production line design device 100. The input unit 130 acquires various types of information used for the processing from the storage unit 120.

The output unit 140 is a functional unit that generates display information and displays the display information on a display (display device) provided in the production line design device 100 or the external device 200. Specifically, the output unit 140 generates production line information indicating the configuration of the production line, the screen information of the module group information pertaining to each module group, and the screen information of an edit screen for receiving the edit of the production line, and displays the information on the display.

The communication unit 150 is a functional unit that performs information communication with the external device 200. Specifically, the communication unit 150 transmits predetermined screen information to the external device 200. The communication unit 150 receives an instruction from the user or the information used for the processing from the external device 200.

An example of the schematic configuration (functional configuration) of the production line design device 100 has been described above.

[Description of Operation]

Next, production line design processing executed by the production line design device 100 will be described.

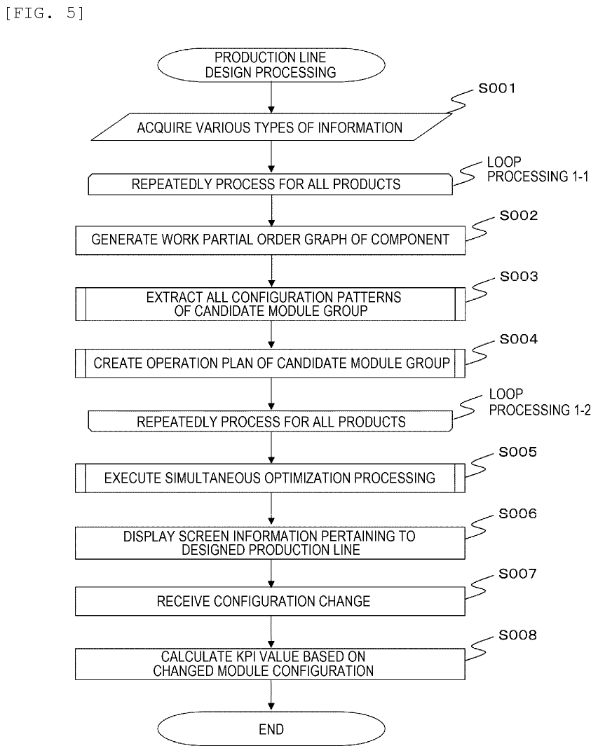

FIG. 5 is a flowchart showing an example of the production line design processing. The processing is started, for example, when an execution instruction from the user is received via the input unit 130.

When the processing is started, the input unit 130 acquires various types of information from the storage unit 120 (step S001). Specifically, the input unit 130 acquires the product CAD information 121, the product quantity information 123, the module group specification information 124, the module specification information 125, the factory layout information 126, and the module operation pattern information 127 from the storage unit 120.

Next, the candidate module group extraction unit 111 repeatedly executes processing of steps S002 to S004 as follows for all products (loop processing 1-1 to 1-2).

In step S002, the candidate module group extraction unit 111 generates a work partial order graph for the components of the product. Specifically, the candidate module group extraction unit 111 uses the product CAD information 121 to generate a graph indicating a work partial order relation (hereinafter, may be referred to as the “work partial order graph”).

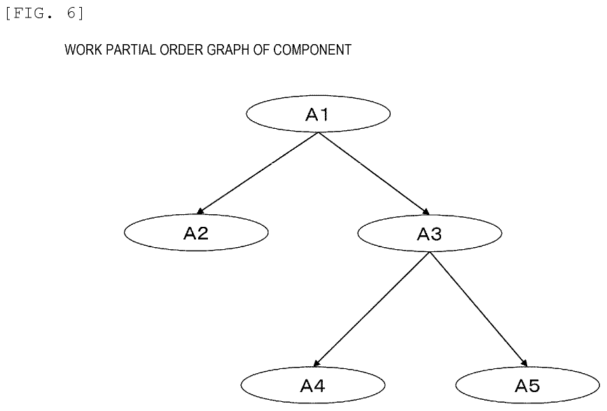

FIG. 6 is a diagram showing an example of the work partial order graph. As shown in the drawing, the work partial order graph includes nodes A1 to A5 indicating the components of the product and directed arcs indicating each assembly relation between the nodes.

Next, the candidate module group extraction unit 111 extracts all configuration patterns of the candidate module group (step S003).

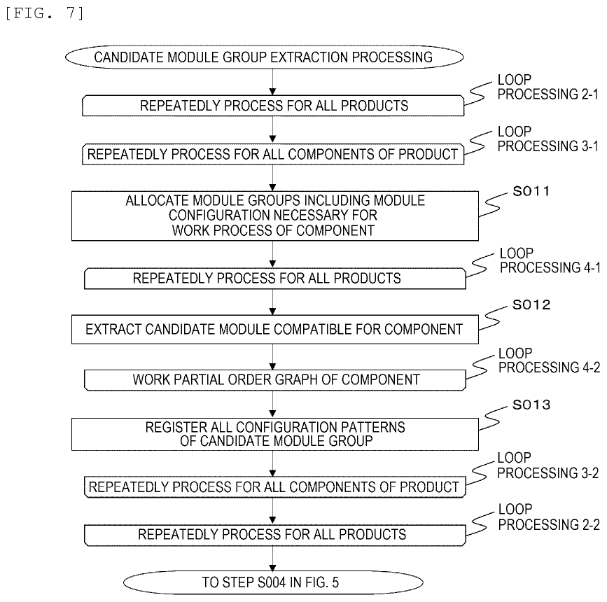

FIG. 7 is a flowchart illustrating an example of the candidate module group extraction processing executed in step S003.

First, the candidate module group extraction unit 111 allocates module groups including a module configuration necessary for the work process of each component (step S011). Specifically, the candidate module group extraction unit 111 specifies the components of the product by using the work partial order graph. The candidate module group extraction unit 111 specifies a process attribute of the specified component from the component attribute information 122. The candidate module group extraction unit 111 specifies the module group associated with the specified process attribute from the module group specification information 124. Accordingly, the module group including the module configuration necessary for the work process of the component is allocated. The module groups allocated in step S011 are set as the candidate module groups.

Next, the candidate module group extraction unit 111 extracts a candidate module that is compatible for the component (step S012). Specifically, the candidate module group extraction unit 111 specifies the record of the module specification information 125 associated with the module attribute of the allocated candidate module group. The candidate module group extraction unit 111 specifies the weight of the component from the component attribute information 122. The candidate module group extraction unit 111 specifies a record in which the weight capacity equal to or more than the weight of the component is registered from among the specified records, and extracts a module registered in the records as a compatible candidate module.

The candidate module group extraction unit 111 repeatedly executes the processing of step S012 for all the candidate module groups allocated in step S011 (loop processing 4-1 to 4-2).

Next, the candidate module group extraction unit 111 registers all configuration patterns of the candidate module groups (step S013). Specifically, the candidate module group extraction unit 111 generates all configuration patterns of the candidate module groups obtained by combining all the candidate modules that are compatible for each module attribute provided in the candidate module groups, and stores the generated all configuration patterns in the storage unit 120.

The candidate module group extraction unit 111 repeatedly executes the processing of steps S011 to S013 for all the components of all the products (loop processing 2-1 to 2-2 and loop processing 3-1 to 3-2).

When the candidate module group extraction unit 111 ends a flow in FIG. 7, the processing proceeds to step S004 in FIG. 5.

In step S004, the operation planning unit 112 creates an operation plan for the candidate module group.

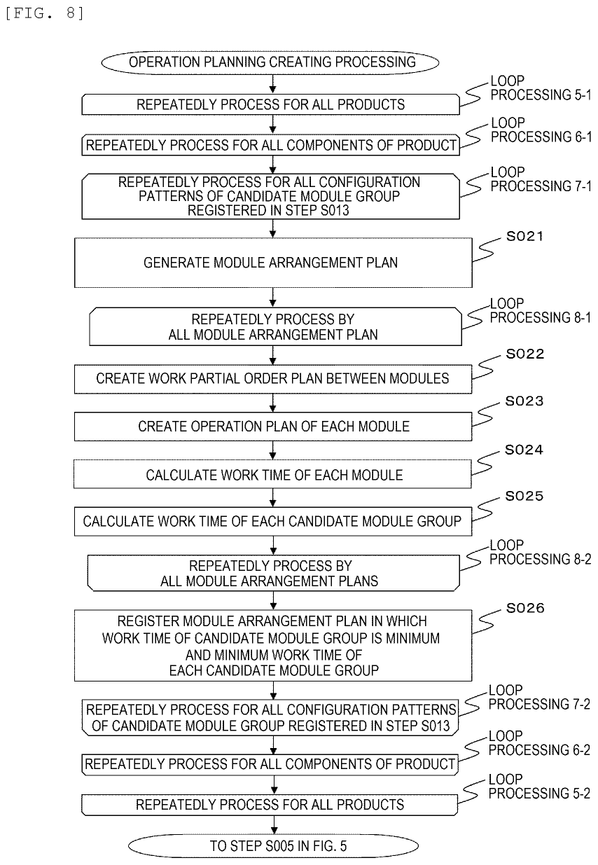

FIG. 8 is a flowchart showing an example of operation planning creating processing.

First, the operation planning unit 112 generates a module arrangement plan in the candidate module group (step S021). Specifically, the operation planning unit 112 generates, as the module arrangement plan, a combination pattern of an arrangement position and a direction of each module in the candidate module group, such as a placement position of the place and a supply direction of the conveyor.

Next, the operation planning unit 112 creates a work partial order plan (operation sequence) between the modules (step S022). Specifically, the operation planning unit 112 specifies the operation pattern of each module using the module operation pattern information 127. The operation planning unit 112 combines the operation patterns of the respective modules to create a work partial order plan between the modules in the candidate module group.

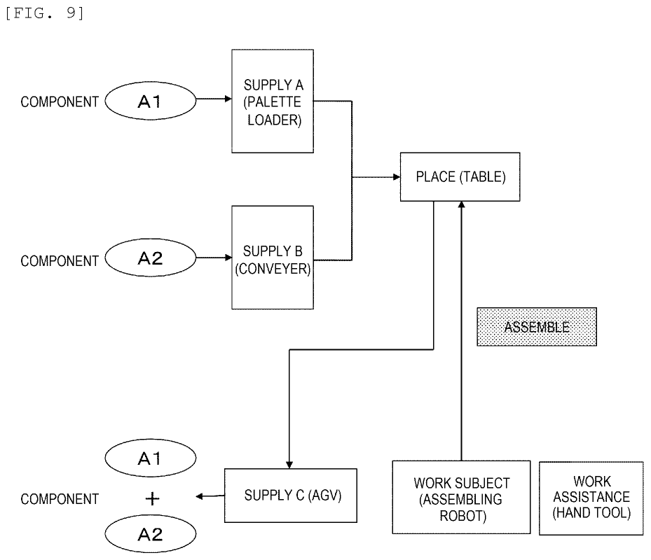

FIG. 9 is a diagram showing an example of the operation sequence between the modules. FIG. 9 shows a series of operation sequences between the modules in which supply A and supply B respectively supply a component A1 and a component A2 to the place, the work subject (assembling robot) assembles the component A1 and the component A2 using the work assistance (hand tool), and the work subject (assembling robot) places the assembled component A1 and component A2 on the supply C (AGV) using the work assistance (hand tool). The operation planning unit 112 creates such a series of work partial order plans.

Next, the operation planning unit 112 creates an operation plan for each candidate module for the configuration pattern of the candidate module group for which the operation partial order plan has been created (step S023). Specifically, the operation planning unit 112 creates an operation of each candidate module using the module operation rule information. The operation of the module is a detailed operation of each candidate module, for example, “in what trajectory the component is picked up” in a case of the picking robot, “in what trajectory the assembly work is performed” in a case of the assembling robot, and “at what speed the component is supplied” in a case of the conveyor.

Next, the operation planning unit 112 calculates a work time of each module for which the operation plan is created (step S024). Specifically, the operation planning unit 112 calculates the work time of each candidate module by simulating the work time of the operation of the candidate module.

Next, the operation planning unit 112 calculates the work time of the candidate module group (step S025). Specifically, the operation planning unit 112 calculates a work time of a series of operations performed in units of the candidate module group, for example, from when the component is supplied to a candidate module group to when the component moves to another candidate module group after assembling work. More specifically, the operation planning unit 112 calculates the work time of the candidate module group by summing up the work times of respective candidate modules in the candidate module group.

The operation planning unit 112 repeatedly executes the processing of steps S022 to S025 for all the module arrangement plans generated in step S021 (loop processing 8-1 to 8-2).

The operation planning unit 112 repeatedly executes the processing of steps S021 to S026 for all the components of all the products and all the configuration patterns of the candidate module groups registered in step S013 (loop processing 5-1 to 5-2, loop processing 6-1 to 6-2, and loop processing 7-1 to 7-2).

When the operation planning unit 112 ends a flow in FIG. 8, the processing proceeds to step S005 in FIG. 5.

In step S005, the work allocation unit 113 and the configuration optimization unit 114 perform simultaneous optimization processing in cooperation with each other.

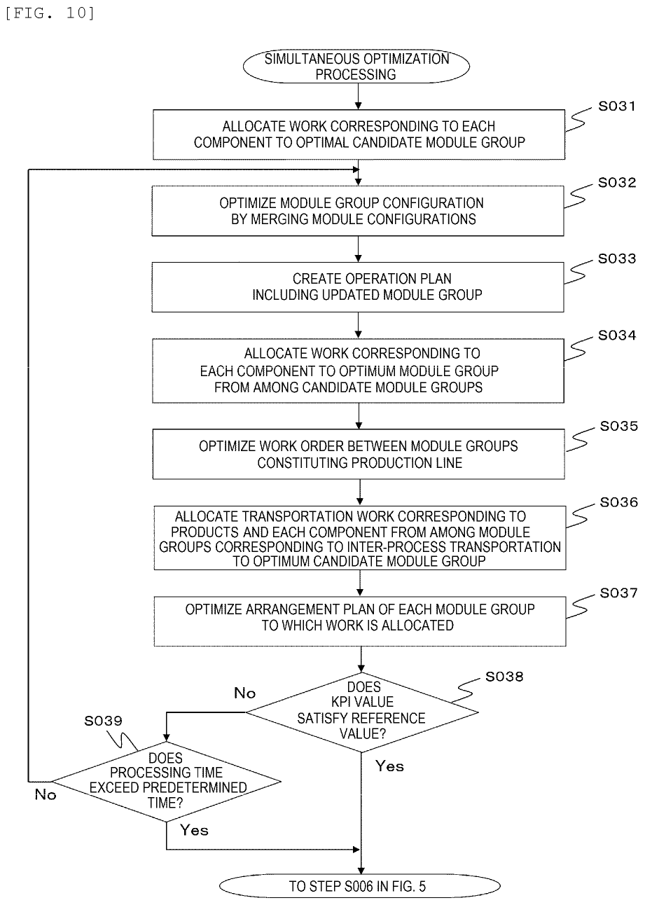

FIG. 10 is a flowchart showing an example of the simultaneous optimization processing.

First, the work allocation unit 113 allocates the work corresponding to each component to an optimal candidate module group (step S031). Specifically, the work allocation unit 113 allocates the work to the candidate module group having a minimum work time and a minimum cost while satisfying the product quantity specified by the product quantity information 123 from the candidate module group corresponding to the work (for example, assembling) corresponding to the component.

In step S031, the allocation of the work to the candidate module group corresponding to the inter-process transportation is not performed. The work allocation processing is executed in step S036 after the work order between the module groups to be described later is optimized.

Next, the configuration optimization unit 114 optimizes the module group configuration by merging the module configurations of the module groups having similar module configurations of the module group to which the work is allocated (step S032).

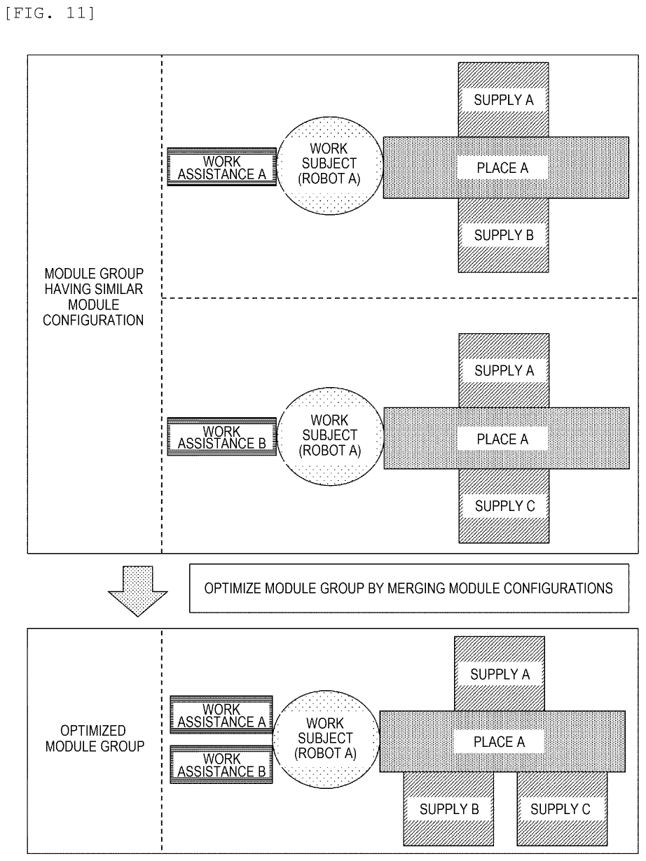

FIG. 11 is a diagram showing an example of optimization of the module group configuration. As shown in the drawing, when there is a similar module group implemented by the same module attribute, the configuration optimization unit 114 optimizes a module group configuration including a module (a robot A, a place A, and supply A) common to both module groups and modules (work assistance A and B, and supply B and C) of different types having the same module attribute by merging these module configurations.

Next, the configuration optimization unit 114 creates an operation plan including the updated module group through the operation planning unit 112 (step S033). Specifically, the configuration optimization unit 114 performs the processing of steps S021 to S026 by using the module group whose configuration is updated as one of the candidate module groups through the operation planning unit 112. That is, the configuration optimization unit 114 generates a module arrangement plan including the candidate module group of the new configuration to perform the operation planning processing on all the candidates of the module group.

Next, the configuration optimization unit 114 allocates the work corresponding to each component to the optimum module group from among the candidate module groups after creating the operation plan including the updated module group (after the processing of steps S021 to S026) (step S034). That is, the configuration optimization unit 114 allocates the work to the candidate module group having the minimum work time and the minimum cost while satisfying the product quantity specified by the product quantity information 123 among the candidate module groups after the operation plan creating processing including the updated candidate module group.

Next, the work order planning unit 115 optimizes the work order between the module groups constituting the production line (step S035). Specifically, the work order planning unit 115 optimizes (determines) the work order to maximize the predetermined KPI in consideration of the operation of each module, the work time of each module group, and the product quantity defined in the module operation pattern information 127. The KPI value may be calculated by the KPI calculation unit 117.

Next, the configuration optimization unit 114 allocates transportation work corresponding to products and each component from among the module groups corresponding to the inter-process transportation (module groups to which the process attribute of the inter-process transportation is associated) to the optimum candidate module group (step S036). Specifically, the configuration optimization unit 114 specifies a module group that performs first work, a module group that involves inter-component supply, and a module group that performs last work based on the optimized work order.

The configuration optimization unit 114 specifies a module group corresponding to the inter-process transportation in which the component is transported to the module group that performs the first work, a module group corresponding to inter-process transportation in which the component is transported from a module group to another module group, and a module group corresponding to inter-process conveyance in which the component is transported from the module group that performs the last work.

The configuration optimization unit 114 specifies the work time registered in step S026 for each candidate module group corresponding to each specified transportation place. The configuration optimization unit 114 calculates a cost of each candidate module group using the module specification information 125. The configuration optimization unit 114 allocates, through the work allocation unit 113, the transportation work of each transportation place to the candidate module group in which each work time and each cost are equal to or less than predetermined values and the predetermined KPI is maximized.

Next, the arrangement unit 116 optimizes an arrangement plan for each module group to which the work is allocated (step S037). Specifically, the arrangement unit 116 uses the factory layout information 126 to generate the arrangement plan indicating the arrangement of each module group to which the work is allocated in the factory. More specifically, the arrangement unit 116 optimizes the arrangement plan by calculating a predetermined KPI value pertaining to the production line for each arrangement plan for each module group in the factory layout through the KPI calculation unit 117 and generating the arrangement plan such that the KPI value is maximized.

The KPI includes, for example, the operation rate, the productivity, and the equipment cost of the production line. Here, the operation rate of the production line is a ratio of an equipment operation time to a factory operation time. The equipment operation time may include the time when at least one module group is operating, or an average operation time of each module group may be set as the equipment operation time.

The productivity is calculated from a production throughput called the number of products produced within a predetermined time. Specifically, the productivity is, for example, a ratio of an actual production volume (for example, 8) to a target production volume per hour (for example, 10). The productivity may be indicated by an actually produced throughput (number).

The equipment cost is an equipment cost of an entire production line. Specifically, the equipment cost is indicated by a value obtained by adding up the equipment costs of the module groups provided in the production line.

Next, the configuration optimization unit 114 determines whether the KPI value satisfies a predetermined reference value (step S038). Specifically, the configuration optimization unit 114 determines whether, for example, the operation rate, the productivity, and the equipment cost of the production line are values satisfying the reference value of each KPI. When it is determined that the reference value is satisfied (Yes in step S038), the configuration optimization unit 114 ends the processing of the present flow. On the other hand, when it is determined that the reference value is not satisfied (No in step S038), the configuration optimization unit 114 causes the processing to proceed to step S039.

In step S039, the configuration optimization unit 114 determines whether a processing time exceeds the predetermined time (for example, several tens of minutes to several hours). When it is determined that the processing time exceeds the predetermined time (Yes in step S039), the configuration optimization unit 114 adopts (registers) an arrangement plan for the module group closest to the reference value at that timing, and ends the processing of the present flow. On the other hand, when it is determined that the predetermined time is not exceeded (No in step S039), the configuration optimization unit 114 causes the processing to proceed to step S032.

For example, regarding whether the reference value is satisfied, for example, it may be determined that the reference value is satisfied when the reference values of a predetermined number of KPIs among a plurality of KPIs are satisfied, or it may be determined that the reference value is satisfied when the reference values of all KPIs are satisfied.

When the flow in FIG. 10 ends, the configuration optimization unit 114 causes the processing to proceed to step S006 in FIG. 5.

In step S006, the output unit 140 generates screen information pertaining to the designed production line (hereinafter, may be referred to as production line display information) and displays the screen information on the display.

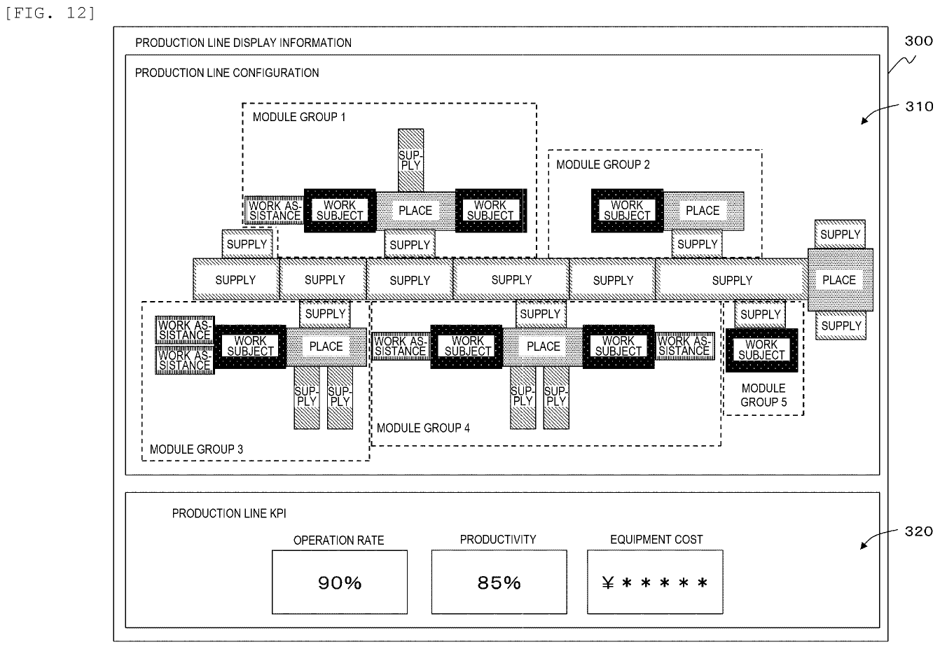

FIG. 12 is a screen example 300 showing an example of the production line display information. As shown in the drawing, the production line display information includes a production line configuration display area 310 and a production line KPI display area 320.

In the production line configuration display area 310, the configuration and an arrangement relation of each module group of the production line arranged in the factory layout are shown. In the production line KPI display area 320, KPI values of the production line including the operation rate, the productivity, and the equipment cost are shown.

When any module displayed in the production line configuration display area 310 is selected through the input unit 130, the output unit 140 generates module group display information and displays the module group display information on the display.

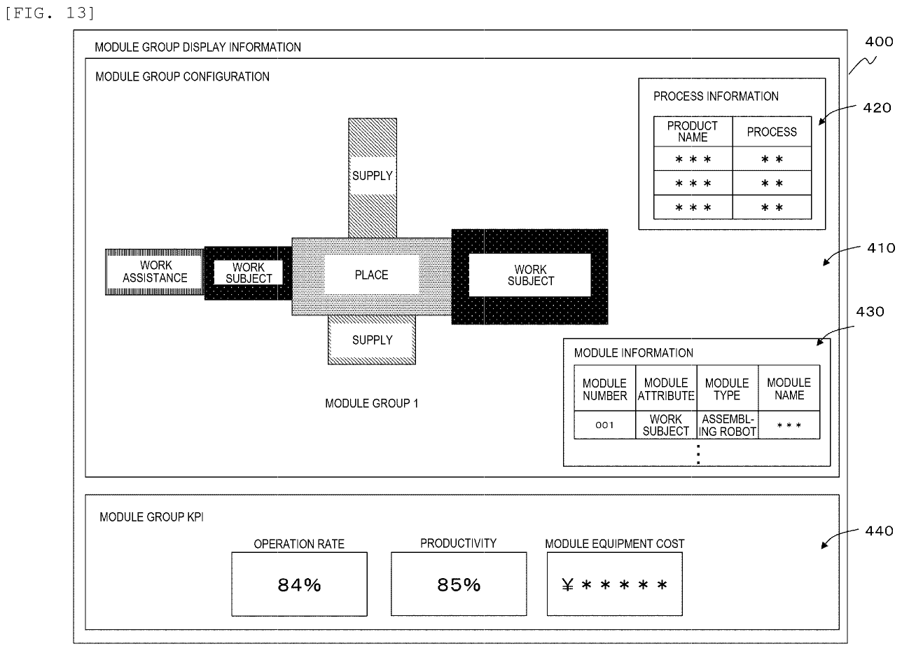

FIG. 13 is a screen example 400 showing an example of the module group display information. As shown in the drawing, the module group display information includes a module group configuration display area 410, a process information display area 420, a module information display area 430, and a module group KPI display area 440.

In the module group configuration display area 410, the configuration of the module group selected from the production line configuration display area, that is, each module attribute and the arrangement in the module group are shown. In the process information display area 420, process information, is displayed, which is information pertaining to the work process performed in a selected module group and to which a product ID and a process ID are associated. The module information display area 430 displays the module information which is information pertaining to the configuration of the selected module group and to which a module number, a module attribute, a module type, and a module name are associated.

In the module group KPI display region 440, the KPI values of the module group, which include the operation rate, the productivity, and the module equipment cost of the selected module group, are shown. Each KPI value of the module group may be calculated in the same manner as each KPI value corresponding to the production line.

In step S007 in FIG. 5, the input unit 130 receives input of a configuration change. Specifically, when receiving instruction input pertaining to the configuration change of the production line from the user, the input unit 130 generates screen information in which the edit of the production line is received (hereinafter, may be referred to as edit screen information) through the output unit 140, and displays the screen information on the display. The input unit 130 receives an edit instruction of the production line from the user via the edit screen information.

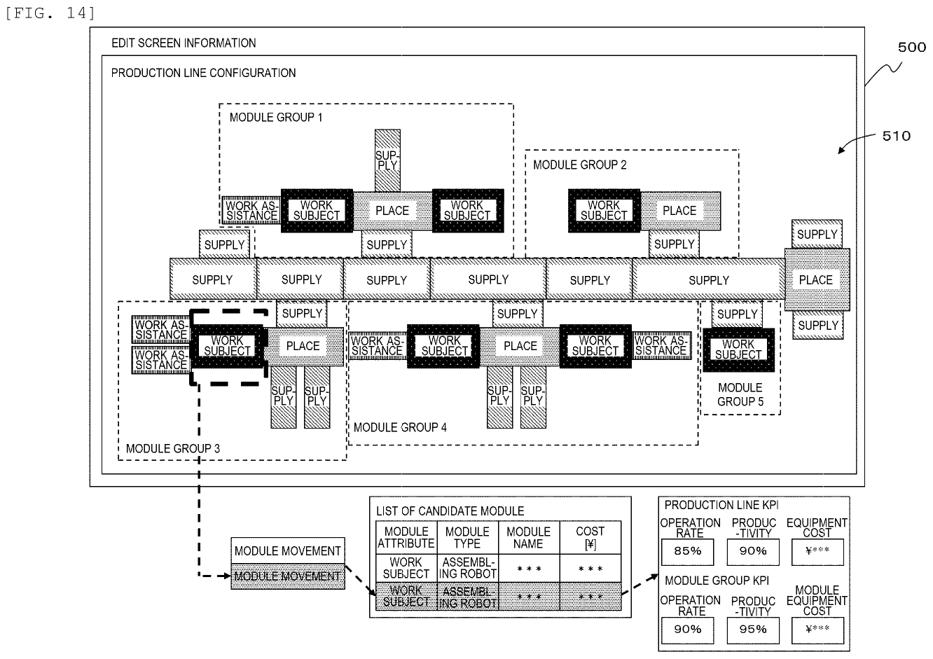

FIG. 14 is a screen example 500 showing an example of the edit screen information. As shown in the drawing, the edit screen information includes a production line configuration display area 510. For example, when receiving input of selection of a module attribute (a work subject in the present example) of a module group (as shown in the drawing, a module group 3 in the present example) and module movement, the input unit 130 generates list information of the candidate module to which the selected module attribute is associated using the module specification information 125. The input unit 130 displays the list information of the candidate module on the display via the output unit 140, and receives selection from the user.

In step S008 in FIG. 5, the adjustment unit 118 calculates a KPI value based on the changed module configuration. Specifically, the adjustment unit 118 changes to the selected candidate module, does not change the other module configurations, and outputs a re-execution instruction of a part of the processing in the operation planning processing and the simultaneous optimization processing to the corresponding processing unit.

Specifically, the module arrangement plan for the selected candidate module is generated by the operation planning unit 112, and the work time of each candidate module and the work time of the module group including the candidate module are calculated for each arrangement plan (corresponding to the processing of steps S021 to S025). The KPI values of the operation rate, the productivity, and the equipment cost are calculated after the work allocation to the optimum module group, the work order of the production line, and the arrangement plan for each module group are optimized by the configuration optimization unit 114 (corresponding to the processing of steps S034, S035, and S037).

The output unit 140 displays at least one of the KPI values of the production line and the KPI value of the module group on the display, and indicates a changed improvement value to the user.

After performing the processing of step S008 in FIG. 5, the configuration optimization unit 114 ends the processing of the present flow.

The production line design processing has been described above.

According to such the production line design device 100, a quasi-optimal solution for the production line can be obtained such that the KPI is further improved without deteriorating the production throughput after the production line is designed.

Hereinafter, an example of a hardware configuration of the production line design device 100 will be described.

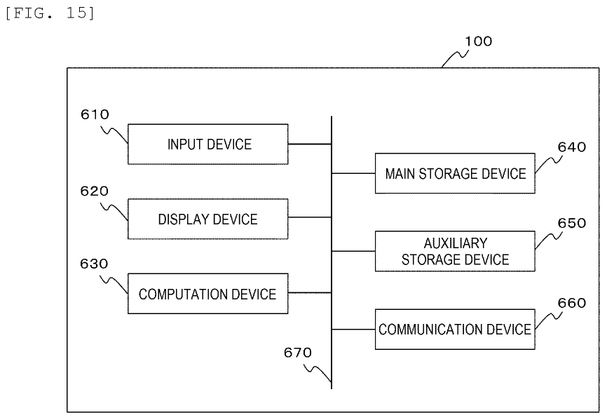

FIG. 15 is a diagram showing an example of the hardware configuration of the production line design device 100. The production line design device 100 is implemented by a high-performance information processing device such as a server device.

As shown in the drawing, the production line design device 100 includes an input device 610, a display device 620, a computation device 630, a main storage device 640, an auxiliary storage device 650, a communication device 660, and a bus 670 that electrically connects these devices to each other.

The input device 610 is an input device such as a touch panel, a keyboard, or a mouse. The display device 620 is a display device such as a liquid crystal display or an organic display.

The computation device 630 is, for example, a central processing unit (CPU). The main storage device 640 is a memory device such as a random access memory (RAM) or a read only memory (ROM).

The auxiliary storage device 650 is a nonvolatile storage device such as a so-called hard disk drive, a solid state drive (SSD), or a flash memory capable of storing digital information.

The communication device 660 is a wired communication device that performs a wired communication via a network cable, or a wireless communication device that performs a wireless communication via an antenna. The communication device 660 performs the information communication with the external device 200 connected to the network N.

An example of the hardware configuration of the production line design device 100 has been described above.

The computation unit 110 of such the production line design device 100 is implemented by a program that causes the computation device 630 to perform the processing. The program is stored in the main storage device 640 or the auxiliary storage device 650, loaded onto the main storage device 640 during execution of the program, and executed by the computation device 630. The input unit 130 is implemented by the input device 610. The output unit 140 is implemented by the display device 620. The storage unit 120 is implemented by the main storage device 640, the auxiliary storage device 650, or a combination thereof. The communication unit 150 is implemented by the communication device 660.

Further, each of the above configurations, functions, processing units, processing means, and the like of the production line design device 100 may be implemented by a hardware by designing a part or all of them by, for example, an integrated circuit. The above configurations and functions may be implemented by a software in which a processor interprets and executes a program for implementing the functions. Information such as a program, a table, and a file for implementing the functions can be stored in a storage device such as a memory, a hard disk, and an SSD, or a recording medium such as an IC card, an SD card, and a DVD.

The invention is not limited to the above embodiments and modifications, and includes various modifications within a scope of the same technical idea. For example, the above embodiments have been described in detail for easy understanding of the invention, and the invention is not necessarily limited to those including all of the configurations described above. A part of a configuration of one embodiment can be replaced with a configuration of another embodiment, and a configuration of another embodiment can be added to a configuration of one embodiment. A part of the configuration of each embodiment may be added to, deleted from, or replaced with another configuration.

In the above description, control lines and information lines are those that are considered necessary for the description, and not all the control lines and the information lines on the product are necessarily shown. In practice, it may be considered that almost all configurations are connected to each other.

### REFERENCE SIGNS LIST

1000: production line design system
100: production line design device
110: computation unit
111: candidate module group extraction unit
112: operation planning unit
113: work allocation unit
114: configuration optimization unit
115: work order planning unit
116: arrangement unit
117: KPI calculation unit
118: adjustment unit
120: storage unit
121: product CAD information
122: component attribute information
123: product quantity information
124: module group specification information
125: module specification information
126: factory layout information
127: module operation pattern information
130: input unit
140: output unit
150: communication unit
610: input device
620: display device
630: computation device
640: main storage device
650: auxiliary storage device
660: communication device
670: bus
200: external device
N: network

1. A production line design device comprising:
a storage unit configured to store product CAD information pertaining to a shape of a product, component attribute information pertaining to an attribute of a component, module group specification information pertaining to a specification of a module group implemented by combining attributes of modules as a production resource of the product for respective work processes of the component, and module specification information pertaining to a specification of the module; and
a computation unit configured to design a production line by executing an equipment design, a control design, a process design, and an arrangement design in this order, wherein
the computation unit includes a candidate module group extraction unit that is a functional unit configured to use the information stored in the storage unit to perform the equipment design, and that is configured to extract a configuration pattern of a candidate module group obtained by combining a candidate of the module group that is work-compatible for each component of the product and the module that is handled in the candidate of the module group.

2. The production line design device according to claim 1, wherein
the storage unit further has module operation rule pattern information pertaining to an operation rule of the module, and
the computation unit further includes an operation planning unit that is a functional unit configured to use the information stored in the storage unit to perform the control design, and that is configured to create an operation sequence of the modules according to the extracted configuration pattern and calculate a work time of the module and a work time of each configuration pattern of the candidate module group based on the operation sequence.

3. The production line design device according to claim 1, wherein
the storage unit further has product quantity information pertaining to a product quantity of the product, and
the computation unit further includes a work allocation unit that is a functional unit configured to use the information stored in the storage unit to perform the process design, and that is configured to allocate work to the candidate of the module group having a minimum work time and cost for each work process of the component.

4. The production line design device according to claim 3, wherein
the computation unit further includes a configuration optimization unit configured to optimize a configuration of the module group after the work allocation.

5. The production line design device according to claim 4, wherein
when a similar module group exists, the configuration optimization unit optimizes the configuration of the module group by merging configurations of the modules provided in the module group.

6. The production line design device according to claim 4, wherein
the configuration optimization unit
creates an operation sequence of the modules in an updated module group according to the optimization,
calculates a work time of the module and a work time of the module group based on the operation sequence, and
allocates work to a candidate of the module group having a minimum work time and cost for each work process of the component among the candidates of the module group including the updated module group.

7. The production line design device according to claim 6, wherein
the computation unit further includes a work order planning unit configured to determine a work order such that a predetermined key performance indicator (KPI) pertaining to the production line is maximized.

8. The production line design device according to claim 1, wherein
the storage unit further has in-factory layout information indicating a layout in a factory, and
the computation unit further includes an arrangement unit that is a functional unit configured to use the information stored in the storage unit to perform the arrangement design, and that is configured to generate an arrangement plan in the factory of the module group to which the work is allocated such that a predetermined KPI pertaining to the production line is maximized.

9. The production line design device according to claim 3, wherein
the computation unit further includes a configuration optimization unit configured to allocate transportation work of each transportation location, for each candidate of the module group corresponding to the transportation work after a work order is determined, such that the work time and the cost are equal to or less than predetermined values and a predetermined KPI pertaining to the production line is maximized.

10. The production line design device according to claim 1, further comprising:
an output unit configured to generate screen information for displaying a configuration of the module group provided in the designed production line and a predetermined KPI value pertaining to the production line.

11. The production line design device according to claim 1, further comprising:
an input unit configured to receive an instruction to change a configuration of the module group provided in the designed production line to another module, and
an adjustment unit configured to perform processing pertaining to the control design, the process design, and the arrangement design using the module according to the change.

12. A production line design system including a production line design device and an external device, wherein
the production line design device includes
a storage unit configured to store product CAD information pertaining to a shape of a product, component attribute information pertaining to an attribute of a component, module group specification information pertaining to a specification of a module group constituted by combining attributes of modules as a production resource of the product for respective work processes of the component, and module specification information pertaining to a specification of the module, and
a computation unit configured to design a production line by executing an equipment design, a control design, a process design, and an arrangement design in this order,
the computation unit includes a candidate module group extraction unit that is a functional unit configured to use the information stored in the storage unit to perform the equipment design, and that is configured to extract a configuration pattern of a candidate module group obtained by combining a candidate of the module group that is work-compatible for each component of the product and the module configured that is handled in the candidate of the module group,
the production line design device further includes a communication unit configured to transmit screen information for displaying a configuration of the designed production line and a predetermined type KPI to the external device, and
the external device transmits an instruction pertaining to processing of the production line design device and acquires the screen information from the production line design device.

13. A production line design method performed by a production line design device, the production line design method comprising:
by the production line design device,
a storage step of storing a product CAD information pertaining to a shape of a product, a component attribute information pertaining to an attribute of a component, a module group specification information pertaining to a specification of a module group constituted by combining attributes of modules as a production resource of the product for respective work processes of the component, and module specification information pertaining to a specification of the module, and
a computation step of designing a production line by executing an equipment design, a control design, a process design, and an arrangement design in this order, wherein
in the computation step, in the equipment design performed using the information stored in the storage step, a candidate module group extracting step of extracting a configuration pattern of a candidate module group obtained by combining a candidate of the module group that is work-compatible for each component of the product and the module that is handled in the candidate of the module group is performed.
